(19) United States
(12) Patent Application Publication
(10) Pub. No.: US 2021/0398846 A1
(43) Pub. Date: Dec. 23, 2021

(54) METHOD FOR AREA SELECTIVE DEPOSITION USING A SURFACE CLEANING PROCESS

(71) Applicant: Tokyo Electron Limited, Tokyo (JP)

(72) Inventors: Kandabara N. Tapily, Albany, NY (US); Shuji Azumo, Hosaka-cho (JP); Yumiko Kawano, Hosaka-cho (JP); Shinichi Ike, Hwaseong-si (KR)

(21) Appl. No.: 17/345,245

(22) Filed: Jun. 11, 2021

Related U.S. Application Data
(60) Provisional application No. 63/040,483, filed on Jun. 17, 2020.

(51) Int. Cl. H01L 21/768; H01L 21/02

(52) U.S. Cl. CPC H01L 21/76834; H01L 21/02074; H01L 21/02065

(57) ABSTRACT

A substrate processing method for area selective deposition. The method includes providing a substrate containing a metal film, a metal-containing liner, and a dielectric film, exposing the substrate to a plasma-excited cleaning gas containing 1) N₂ gas and H₂ gas, 2) N₂ gas followed by H₂ gas, or 3) H₂ gas followed by N₂ gas, forming a blocking layer on the metal film and on the metal-containing liner, and selectively depositing a material film on the dielectric film.

### CROSS REFERENCE TO RELATED PATENTS AND APPLICATIONS

This application claims priority to and the benefit of the filing date of U.S. Provisional Patent Application No. 63/040,483, filed Jun. 17, 2020, which application is incorporated herein by reference in its entirety.

### FIELD OF THE INVENTION

The present invention relates to semiconductor processing and semiconductor devices, and more particularly, to methods for area selective film formation on a substrate using a surface cleaning process.

### BACKGROUND OF THE INVENTION

As device size is getting smaller, the complexity in semiconductor device manufacturing is increasing. The cost to produce the semiconductor devices is also increasing and cost effective solutions and innovations are needed. As smaller transistors are manufactured, the critical dimension (CD) or resolution of patterned features is becoming more challenging to produce. Selective deposition of thin films is a key step in patterning in highly scaled technology nodes. New deposition methods are required that provide selective film formation on different material surfaces.

### SUMMARY OF THE INVENTION

A substrate processing method for area selective deposition on a substrate. According to one embodiment, the method includes providing a substrate containing a metal film, a metal-containing liner, and a dielectric film, exposing the substrate to a plasma-excited cleaning gas containing 1) N₂ gas and H₂ gas, 2) N₂ gas followed by H₂ gas, or 3) H₂ gas followed by N₂ gas, forming a blocking layer on the metal film and on the metal-containing liner, and selectively depositing a material film on the dielectric film.

### BRIEF DESCRIPTION OF THE DRAWINGS

A more complete appreciation of embodiments of the invention and many of the attendant advantages thereof will become readily apparent with reference to the following detailed description, particularly when considered in conjunction with the accompanying drawings, in which:

FIG. 1 is a process flow diagram for a method of selectively forming a film on a substrate according to an embodiment of the invention;

FIGS. 2A-2E show schematic cross-sectional views of a method of selectively forming a film on a substrate according to an embodiment of the invention;

FIGS. 3A and 3B shows experimental results for selectively forming a film on a substrate according to an embodiment of the invention; and

FIGS. 4A and 4B shows experimental results for non-selectively forming a film on a substrate.

### DETAILED DESCRIPTION OF SEVERAL EMBODIMENTS

Embodiments of the invention provide methods for area selective deposition on a substrate. Embodiments of the invention may be applied to surface sensitive deposition processes such as atomic layer deposition (ALD), chemical vapor deposition (CVD), and spin-on deposition. The area selective deposition provides a reduced number of processing steps compared to conventional lithography and etching process and can provide an improved margin for line-to-line breakdown and electrical leakage performance in the semiconductor device.

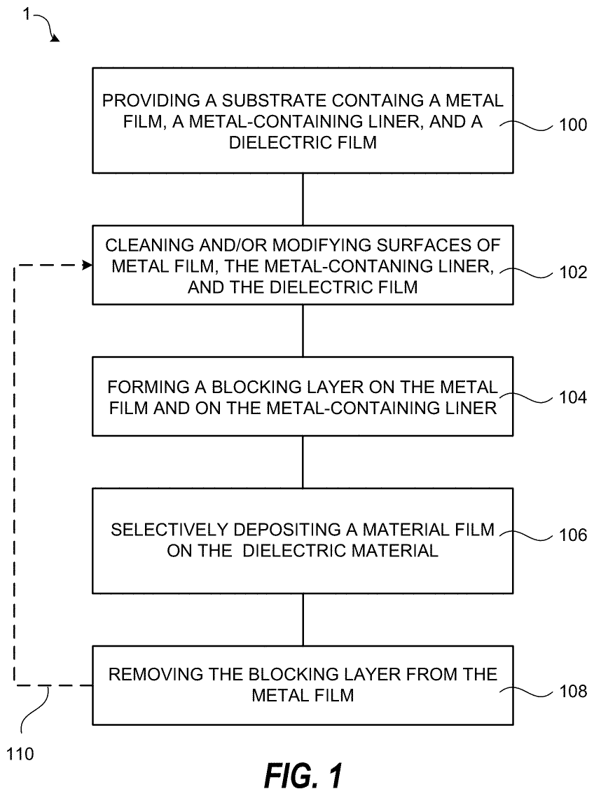

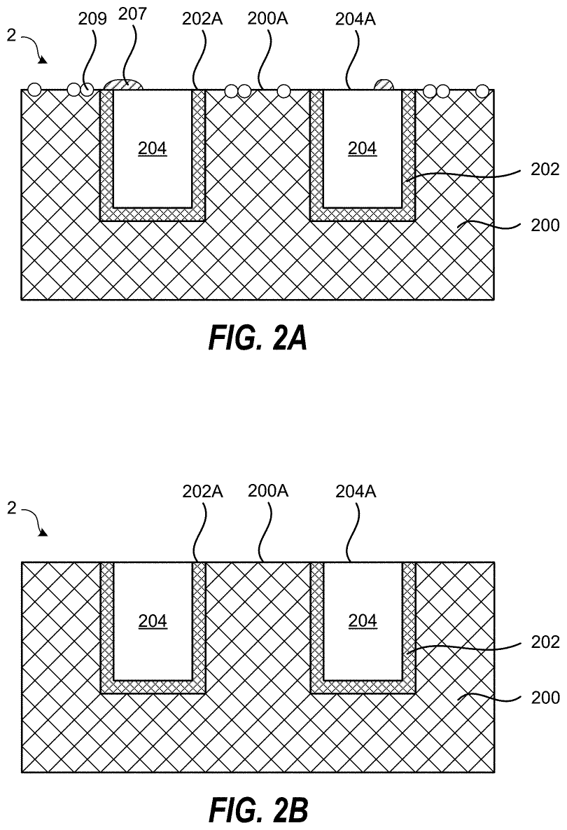

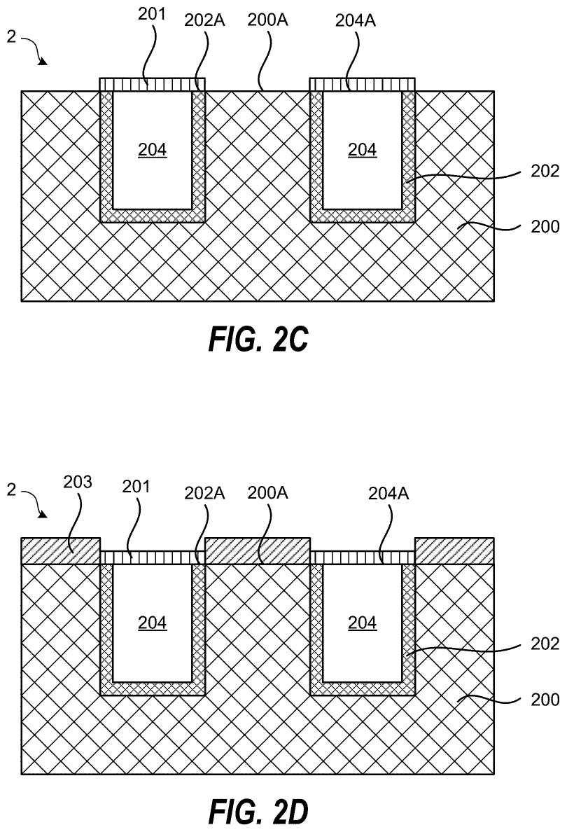

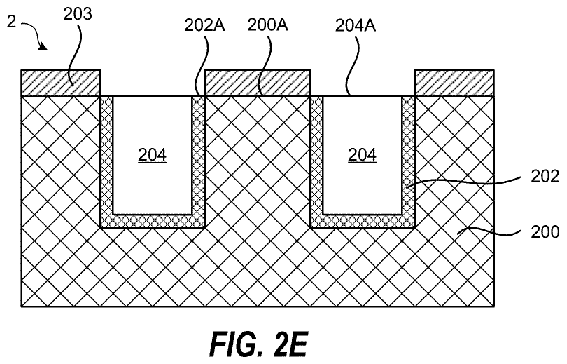

Referring now to FIGS. 1 and 2A-2E, the process flow diagram 1 includes, in 100, providing substrate 2 containing a metal film 204 having a surface 204A, a metal-containing liner 202 having a surface 202A, and a dielectric film 200 having a surface 200A. In the example shown in FIG. 2A, the incoming planarized substrate 2 has the surfaces 200A, 202A, and 204A in the same horizontal plane. However, in other examples, one or more of the surfaces 200A, 202A, and 204A may be vertically offset. The exemplary substrate 2 shown in FIG. 2A has the metal-containing liner 202 surrounding the metal film 204, and the dielectric film 200 surrounding the metal-containing liner 202. This type of film structure is commonly found in integrated circuits where the metal-containing liner 202 forms a diffusion barrier, a deposition seed layer for the metal film 204, or both, between the metal film 204 and the dielectric film 200. However, the methods described herein may also be used for a variety of other film structures having two or more adjacent materials with exposed surfaces.

The metal film 204 can include a pure or a substantially pure low-resistivity metal found in metal interconnects, for example Cu, Al, Ta, Ti, W, Ru, Co, Ni, Mo, Rh, or Ir. The dielectric film 200 can, for example, contain SiO₂, a low-k material, or a high-k material. In one example, the dielectric film 200 does not contain a metal element. The metal-containing liner 202 can, for example, contain a metal compound such as a metal nitride (e.g., TiN or TaN). In another example, the metal-containing liner 202 can include a laminate containing metal-compound layer and a metal layer (e.g., TaN/Ta, TaN/Co, or TaN/Ir). In one example, the dielectric film 200 includes SiO₂ or a low-k material, the metal-containing liner includes a laminate containing TaN/Ta, TaN/Co, or TaN/Ir, and the metal includes Cu. In another example, the dielectric film includes SiO₂ or a low-k material, the metal-containing liner includes TaN, and the metal includes Ru or Co.

In the example shown in FIG. 2A, the incoming planarized substrate 2 has the surfaces 200A, 202A, and 204A in the same horizontal plane. The planarization process can include a chemical mechanical polishing (CMP) process that uses a polishing pad and a chemical slurry. The CMP process can leave polishing residue and oxidized material on the planarized substrate 2, and a gaseous surface cleaning process may be used for removing those contaminants.

FIG. 2A schematically shows polishing residue 207 and metal-containing contaminants 209 (e.g., oxidized Cu) on the surfaces of the planarized substrate 2 that need to be removed in a surface cleaning process before performing area selective deposition. The surface cleaning process can also provide the desired surface termination for the area selective deposition, or a separate surface modification process may be performed to achieve the desired surface termination. One example of a surface termination includes the formation of hydroxyl-groups (—OH) on the surface 200A of the dielectric film 200.

The surface cleaning process can include exposing the substrate to a plasma-excited cleaning gas for a time period that effectively removes the residue 207 and the metal-containing contaminants 209 from the exposed surfaces. Further, the surface cleaning process may chemically reduce the exposed metal-containing liner 202. For example, the Ta metal content of a TaN or an oxidized TaN metal-containing liner 202 may increase by the surface cleaning process, thereby more resembling the chemical composition of metal film 204, which can improve selective formation of a blocking layer on the metal-containing liner 202 and on the metal film 204 relative to on the dielectric film 200. According to embodiments of the invention, the surface cleaning process includes exposing the substrate 2 to a plasma-excited cleaning gas containing 1) N₂ gas and H₂ gas, 2) N₂ gas followed by H₂ gas, or 3) H₂ gas followed by N₂ gas. The exposure in 1) includes simultaneous exposure of the plasma-excited N₂ gas and the plasma-excited H₂ gas, but there is no temporal overlap between the plasma-excited H₂ gas exposure and the plasma-excited N₂ gas exposure in 2) and 3). Plasma conditions may be selected that do not damage the materials of the substrate 2. The resulting clean substrate 2 is schematically show in FIG. 2B.

In 104, the method includes forming a blocking layer 201 on the metal film 200 and on the metal-containing liner 202. This is schematically shown in FIG. 2C. The blocking layer 201 can physically prevent or reduce subsequent deposition of a material film on the metal film 200 and the metal-containing liner 202 in an area selective deposition process. According to one embodiment, the blocking layer 201 includes a self-assembled monolayer (SAM) that is selectively formed on the metal film 204 and on the metal-containing liner 202 relative to the dielectric film 200. The blocking layer 201 may be formed by exposing the substrate 2 to a reactant gas or a liquid that contains a molecule that is capable of selectively forming the SAM. A SAM is an molecular assembly that is spontaneously formed on substrate surfaces by adsorption and are organized into more or less large ordered domains. A SAM can include a molecule that possesses a head group, a tail group, and a functional end group. A SAM is created by the chemisorption of head groups onto the substrate surface from the vapor phase or liquid phase at room temperature or above room temperature, followed by a slow organization of the tail groups. Initially, at small molecular density on the surface, adsorbate molecules form either a disordered mass of molecules or form an ordered two-dimensional “lying down phase”, and at higher molecular coverage, over a period of minutes to hours, begin to form three-dimensional crystalline or semicrystalline structures on the substrate surface. The head groups assemble together on the substrate, while the tail groups assemble far from the substrate.

The head group of the molecule forming the SAM may be selected in view of the ability of the molecule to chemically bond to the different chemical species on different surfaces. Some examples of molecules that can form a SAM on a metal film and on a metal-containing liner contain a head group that includes a thiol or a carboxylate. Some examples of thiols include 1-octadecylthiol (CH₃(CH₂)₁₇SH), 1-dodecylthiol (CH₃(CH₂)₁₇SH), and perfluorodecanethiol (CF₃(CF₂)₇CH₂CH₂SH). According to one embodiment of the invention, the molecule forming the SAM can include a fluorinated alkyl thiol, for example perfluorodecanethiol. Many fluorinated alkyl thiols contain a thiol (—SH) head group, and a CFₓ-containing tail group and functional end group.

In FIG. 2B, the surface 204A of the metal film 204 and the surface 202A of the metal-containing liner 202 may be at least substantially free of oxygen following the surface cleaning process and therefore a SAM blocking layer 201 can easily form on the metal film 204 and on the metal-containing liner 202. In contrast, the dielectric film 200 can include oxygen-containing species, for example a SiO₂ dielectric, thereby preventing the SAM blocking layer 201 from forming on the dielectric film 200.

In 106, the method includes selectively depositing a material film 203 on the dielectric film 200, but deposition of the material film 203 on the metal film 204 and on the metal-containing liner 202 is at least substantially blocked or delayed by the blocking layer 201. This is schematically shown in FIG. 2D.

In some examples, the material film 203 can contain SiO₂, a low-k material (e.g., SiCOH), or a high-k material (e.g., a metal oxide). In one example, SiO₂ may be deposited by sequentially exposing the substrate 2 to a metal-containing catalyst (e.g., Al(CH₃)₃) and a silanol gas. The exposure to the silanol gas can be performed in the absence of any oxidizing and hydrolyzing agent, at a substrate temperature of approximately 150° C., or less. For example, the silanol gas may be selected from the group consisting of tris(tert-pentoxy) silanol, tris(tert-butoxy) silanol, and bis(tert-butoxy)(isopropoxy) silanol. In some examples, the metal oxide can contain HfO₂, ZrO₂, or Al₂O₃. The metal oxide can, for example, be deposited by ALD or plasma-enhanced ALD (PEALD). For example, the metal oxide may be deposited by ALD using alternating exposures of a metal-containing precursor and an oxidizer (e.g., H₂O, H₂O₂, plasma-excited O₂ or O₃).

In 108, the blocking layer may be removed from the metal film 204 and the metal-containing liner 204, for example be heating the substrate 2. The resulting substrate 2 is schematically show in FIG. 2E.

According to one embodiment, shown by the process arrow 110, steps 102-108 may be repeated at least once to increase a thickness of the material film 203 that is selectively deposited on the dielectric film 204.

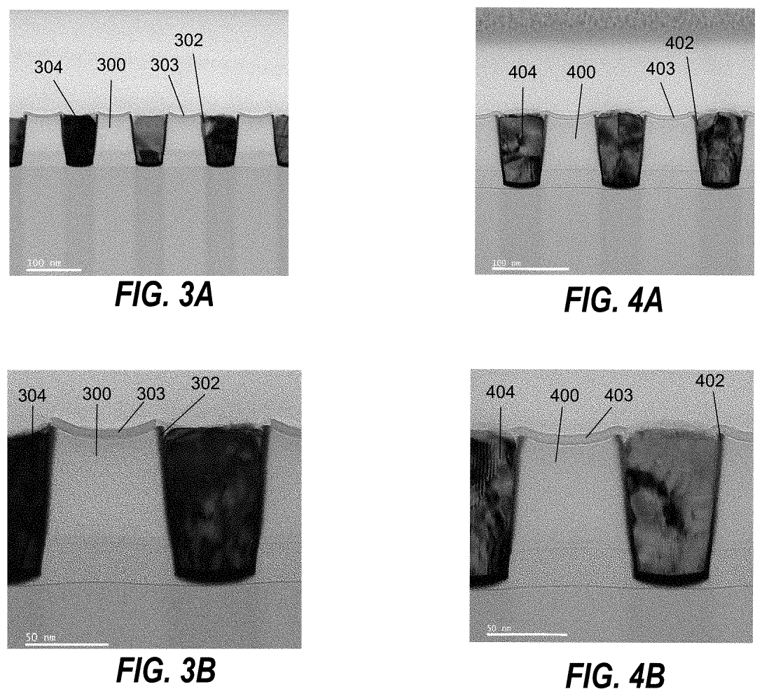

FIGS. 3A and 3B shows experimental results for selectively forming a film on a substrate according to an embodiment of the invention. The cross-sectional SEM images, at different magnifications, show a substrate containing a metal film 304 (i.e., Cu), a metal-containing liner 302 (i.e., a TaN/Ta laminate) surrounding the metal film 304, and a dielectric film 300 (i.e., a low-k dielectric) surrounding the metal-containing liner 302. A SAM (not discernable in the images) containing a thiol was formed on the metal film 304 and on the metal-containing liner 302. Further, an Al₂O₃ film 303 was selectively deposited on the dielectric film 300. The Al₂O₃ film 303 was deposited by vapor phase deposition using alternating exposures of an aluminum precursor and an oxidizer. Prior to the formation of the SAM and the deposition of the Al₂O₃ film 303, a surface cleaning process was performed to remove polishing residue and oxidized material from the exposed surfaces. The surface cleaning process included exposing the substrate to plasma-excited etching gas containing H₂ gas and N₂ gas. The results in FIGS. 3A and 3B show that the surface cleaning process enabled area selective deposition on the dielectric film 300 relative to the metal-containing liner 302 and the metal film 304.

FIGS. 4A and 4B shows experimental results for non-selectively forming a film on a substrate. The cross-sectional SEM images, at different magnifications, show a substrate that contained the same film structure as the substrate in FIGS. 3A and 3B; a metal film 404 (i.e., Cu), a metal-containing liner 402 (i.e., a TaN/Ta laminate) surrounding the metal film 404, and a dielectric film 400 (i.e., a low-k dielectric) surrounding the metal-containing liner 402. A SAM (not discernable in the images) containing a thiol was formed on the metal film 404. The surface cleaning process prior to forming the SAM and the deposition of the Al₂O₃ film 403 included exposing the substrate to plasma-excited etching gas containing H₂ gas but not plasma-excited N₂ gas. The results in FIGS. 4A and 4B show that the surface cleaning process did not enabled area selective deposition on the dielectric film 400 since the Al₂O₃ film 403 was also deposited on the metal-containing liner 402.

Methods for selective film deposition that reduces lateral film formation by using a blocking layer have been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A substrate processing method, comprising:
providing a substrate containing a metal film, a metal-containing liner, and a dielectric film;
exposing the substrate to a plasma-excited cleaning gas containing 1) N₂ gas and H₂ gas, 2) N₂ gas followed by H₂ gas, or 3) H₂ gas followed by N₂ gas;
forming a blocking layer on the metal film and on the metal-containing liner; and
selectively depositing a material film on the dielectric film.

2. The method of claim 1, wherein the metal-containing liner contains a metal compound that includes TiN or TaN.

3. The method of claim 1, wherein the metal-containing liner contains a laminate of TaN/Ta, TaN/Co, or TaN/Ir.

4. The method of claim 1, wherein the metal film includes Cu, Al, Ta, Ti, W, Ru, Co, Ni, Mo, Rh, or Ir.

5. The method of claim 1, wherein the dielectric film includes SiO₂, a low-k material, or a high-k material.

6. The method of claim 1, wherein the material film includes SiO₂, a metal oxide, or a metal nitride.

7. The method of claim 6, wherein the metal oxide contains HfO₂, ZrO₂, or Al₂O₃.

8. The method of claim 1, wherein the blocking layer contains a self-assembled monolayer (SAM).

9. The method of claim 8, wherein the SAM includes a thiol.

10. The method of claim 9, wherein the thiol includes perfluorodecanethiol.

11. A substrate processing method, comprising:
providing a substrate containing a metal film, a metal-containing liner surrounding the metal film, and a dielectric film surrounding the metal-containing liner;
exposing the substrate to a plasma-excited cleaning gas containing 1) N₂ gas and H₂ gas, 2) N₂ gas followed by H₂ gas, or 3) H₂ gas followed by N₂ gas;
forming a blocking layer on the metal film and on the metal-containing liner; and
depositing a material film on the dielectric film.

12. The method of claim 11, wherein the metal-containing liner contains a metal compound that includes TiN or TaN.

13. The method of claim 11, wherein the metal-containing liner contains a laminate of TaN/Ta, TaN/Co, or TaN/Ir.

14. The method of claim 11, wherein the metal film includes Cu, Al, Ta, Ti, W, Ru, Co, Ni, Mo, Rh, or Ir.

15. The method of claim 11, wherein the dielectric film includes SiO₂, a low-k material, or a high-k material.

16. The method of claim 11, wherein the material film includes SiO₂, a metal oxide, or a metal nitride.

17. The method of claim 16, wherein the metal oxide contains HfO₂, ZrO₂, or Al₂O₃.

18. The method of claim 11, wherein the blocking layer contains a self-assembled monolayer (SAM).

19. The method of claim 18, wherein the SAM includes a thiol.

20. The method of claim 19, wherein the thiol includes perfluorodecanethiol.
